(19) United States
(12) Patent Application Publication
(10) Pub. No.: US 2023/0235459 A1
(43) Pub. Date: Jul. 27, 2023

(54) APPARATUS FOR FORMING SINGLE CRYSTAL PIEZOELECTRIC LAYERS USING LOW-VAPOR PRESSURE METALORGANIC PRECURSORS IN CVD REACTORS WITH TEMPERATURE-CONTROLLED INJECTOR COLUMNS AND METHODS OF FORMING SINGLE CRYSTAL PIEZOELECTRIC LAYERS USING THE SAME

(71) Applicant: Akoustis, Inc., Huntersville, NC (US)

(72) Inventors: Craig Moe, Penfield, NY (US); Jeffrey M. Leathersich, Rochester, NY (US)

(21) Appl. No.: 17/582,613

(22) Filed: Jan. 24, 2022

(51) Int. Cl. C23C 16/455; C23C 16/52; C23C 16/18; C30B 25/16; C30B 25/14; H01L 41/35

(52) U.S. Cl. CPC C23C 16/4557; C23C 16/52; C23C 16/18; C30B 25/16; C30B 25/14; H01L 41/35

(57) ABSTRACT

An apparatus includes a chemical vapor deposition (CVD) reactor, an injector column that provides a metal organic precursor vapor into the CVD reactor, a heater in thermal communication with the injector column, and a control circuit configured to control the heater and thereby maintain the metal organic precursor vapor in the injector column above a saturation temperature. The control circuit may be configured to control the heater to maintain a temperature of the metal organic precursor vapor in the injector column in a temperature range from about 85 degrees Centigrade to about 200 degrees Centigrade. A temperature of the metal organic precursor vapor entering the injector column may be in a range from about 160 degrees Centigrade to about 200 degrees Centigrade and a pressure of the metal organic precursor vapor entering the injector column may be in a range from about 50 mbar to about 1000 mbar.

### CROSS-REFERENCE TO RELATED APPLICATIONS AND CLAIM FOR PRIORITY

The present application incorporates by reference, for all purposes, the following concurrently filed patent applications, all commonly owned: U.S. patent application Ser. No. 14/298,057, (Attorney Docket No. A969RO-000100US) entitled “RESONANCE CIRCUIT WITH A SINGLE CRYSTAL CAPACITOR DIELECTRIC MATERIAL”, filed Jun. 6, 2014 (now U.S. Pat. No. 9,673,384 issued Jun. 6, 2017), U.S. patent application Ser. No. 14/298,076, (Attorney Docket No. A969RO-000200US) entitled “ACOUSTIC RESONATOR DEVICE WITH SINGLE CRYSTAL PIEZO MATERIAL AND CAPACITOR ON A BULK SUBSTRATE”, filed Jun. 6, 2014 (now U.S. Pat. No. 9,537,465 issued Jan. 3, 2017), U.S. patent application Ser. No. 14/298,100, (Attorney Docket No. A969RO-000300US) entitled “INTEGRATED CIRCUIT CONFIGURED WITH TWO OR MORE SINGLE CRYSTAL ACOUSTIC RESONATOR DEVICES”, filed Jun. 6, 2014 (now U.S. Pat. No. 9,571,061 issued Feb. 14, 2017), U.S. patent application Ser. No. 14/341,314, (Attorney Docket No.: A969RO-000400US) entitled “WAFER SCALE PACKAGING”, filed Jul. 25, 2014, U.S. patent application Ser. No. 14/449,001, (Attorney Docket No.: A969RO-000500US) entitled “MOBILE COMMUNICATION DEVICE CONFIGURED WITH A SINGLE CRYSTAL PIEZO RESONATOR STRUCTURE”, filed Jul. 31, 2014 (now U.S. Pat. No. 9,716,581 issued Jul. 25, 2017), U.S. patent application Ser. No. 14/469,503, (Attorney Docket No.: A969RO-000600US) entitled “MEMBRANE SUBSTRATE STRUCTURE FOR SINGLE CRYSTAL ACOUSTIC RESONATOR DEVICE”, filed Aug. 26, 2014, and U.S. patent application Ser. No. 16/784,843 (Attorney Docket No. 181246-00022) entitled “APPARATUS FOR FORMING SINGLE CRYSTAL PIEZOELECTRIC LAYERS USING LOW-VAPOR PRESSURE METALORGANIC PRECURSORS IN CVD SYSTEMS AND METHODS OF FORMING SINGLE CRYSTAL PIEZOELECTRIC LAYERS USING THE SAME”, filed Feb. 7,2020.

### BACKGROUND

The present invention relates generally to electronic devices. More particularly, the present invention provides techniques related to a method of manufacture and a structure for bulk acoustic wave resonator devices, single crystal bulk acoustic wave resonator devices, single crystal filter and resonator devices, and the like. Merely by way of example, the invention has been applied to a single crystal resonator device for a communication device, mobile device, computing device, among others.

Wireless data communications can utilize RF filters operating at frequencies around 5 GHz and higher. It is known to use Bulk acoustic Wave Resonators (BAWR) incorporating polycrystalline piezoelectric thin films for some applications. While some polycrystalline based piezoelectric thin film BAWRs may be adequate for filters operating at frequencies from about 1 to 3 GHz, applications at frequencies around 5 GHz and above may present obstacles due to the reduced crystallinity associated with such thin poly-based films.

### SUMMARY

Some embodiments of the inventive subject matter provide an apparatus for forming semiconductor films. The apparatus includes a chemical vapor deposition (CVD) reactor, an injector column that provides a metal organic precursor vapor into a reactor chamber of the CVD reactor, a heater in thermal communication with the injector column, and a control circuit configured to control the heater and thereby maintain the metal organic precursor vapor in the injector column above a saturation temperature. The control circuit may be configured to control the heater to maintain a temperature of the metal organic precursor vapor in the injector column in a temperature range from about 85 degrees Centigrade to about 200 degrees Centigrade.

In some embodiments, the apparatus includes a fluid channel in thermal communication with the injector column and a fluid circulation system configured to pass a fluid through the fluid channel. The heater may be in thermal communication with the fluid.

In some embodiments, a temperature of the metal organic precursor vapor entering the injector column may be in a range from about 160 degrees Centigrade to about 200 degrees Centigrade and a pressure of the metal organic precursor vapor entering the injector column may be in a range from about 50 mbar to about 1000 mbar.

In some embodiments, the apparatus may further include a heated precursor line coupled to the injector column. The heated precursor line may be configured to maintain a temperature of a metal organic precursor vapor delivered to the injector column in a range from about 160 degrees Centigrade to about 200 degrees Centigrade.

Further embodiments provide an apparatus for forming semiconductor films. The apparatus includes a CVD reactor, an injector column that provides a metal organic precursor vapor into a reactor chamber of the CVD reactor, a heat exchanger in thermal communication with the injector column, and a fluid circulation system in fluid communication with the heat exchanger and configured to maintain a temperature of the metal organic precursor vapor in the injector column in a range from about 85 degrees Centigrade to about 200 degrees Centigrade. The fluid circulation system may be configured to circulate a fluid through the heat exchanger and comprises a control circuit is configured to control a temperature of the fluid. The fluid circulation system may include a chiller and/or a heater and the control circuit may be configured to control the chiller and/or the heater. A temperature of the metal organic precursor vapor entering the injector column may be in a range from about 160 degrees Centigrade to about 200 degrees Centigrade and a pressure of the metal organic precursor vapor entering the injector column may be in a range from about 50 mbar to about 1000 mbar. The apparatus may further include a heated precursor line coupled to the injector column. The heated precursor line may be configured to maintain a temperature of a metal organic precursor vapor delivered to the injector column at a temperature in a range from about 160 degrees Centigrade to about 200 degrees Centigrade.

Still further embodiments provide methods of forming semiconductor films. The methods include providing a metal organic precursor vapor to an injector column of a CVD reactor and controlling a heater in thermal communication with the injector column such that the metal organic precursor vapor in the injector column is maintained above a saturation temperature of the metal organic precursor vapor. Controlling heater may include controlling the heater to maintain a temperature of the metal organic precursor vapor in the injector column in a temperature range from about 85 degrees Centigrade to about 200 degrees Centigrade. The methods may further include providing a fluid channel in thermal communication with the injector column and a fluid circulation system configured to pass a fluid through the fluid channel, wherein the heater is in thermal communication with the fluid. A temperature of the metal organic precursor vapor entering the injector column may be in a range from about 160 degrees Centigrade to about 200 degrees Centigrade and a pressure of the metal organic precursor vapor entering the injector column may be in a range from about 50 mbar to about 1000 mbar. The methods may further include heating a precursor line that provides the metal organic precursor vapor to the injector column. The heated precursor line may be configured to maintain a temperature of a metal organic precursor vapor delivered to the injector column in a range from about 160 degrees Centigrade to about 200 degrees Centigrade.

### BRIEF DESCRIPTION OF THE DRAWINGS

FIG. 1 is a schematic representation of a CVD reactor with a temperature-controlled injector column for receiving a preheated low vapor pressure metal organic (MO) precursor according to some embodiments of the invention.

FIG. 2 is a schematic representation of a CVD reactor with a temperature-controlled injector column utilizing a temperature-controlled fluid circulation system according to some embodiments of the invention.

FIG. 3 is a schematic representation of a CVD reactor with a temperature-controlled injector column utilizing a temperature-controlled fluid circulation system according to some embodiments of the invention.

FIG. 4 is a schematic representation of a CVD system using a preheated line and a temperature-controlled injector column according to some embodiments according to the invention.

FIG. 5 is a schematic illustration of a planetary wafer transport that rotates in a horizontal flow CVD reactor with a temperature-controlled injector column according to some embodiments according to the invention.

### DETAILED DESCRIPTION OF EMBODIMENTS

According to some embodiments of the present invention, techniques generally related to electronic devices are provided. More particularly, the present invention provides techniques related to a method of manufacture and structure for, for example, bulk acoustic wave resonator devices, single crystal resonator devices, single crystal filter and resonator devices, and the like. These types of devices have been applied to a single crystal resonator device for communication devices, mobile devices, and computing devices, among others.

Embodiments according to the invention can utilize low vapor pressure metalorganic (MO) precursors for the CVD formation of single crystal piezoelectric layers that incorporate dopants (such as Scandium Sc) and Yttrium Y) at relatively high concentrations by heating the low vapor pressure MO precursor to a relatively high temperature (such as greater than 150 degrees Centigrade). For example, in some embodiments according to the invention, a CVD system can heat a low vapor pressure MO precursor, such as, tris(methylcy-clopentadyenil)Sc (i.e., (Cp)₃Sc)) and MeCp₃Sc or Cp₃Yb and MeCp₃Yb, to at least 150 degrees Centigrade. Other low vapor pressure MO precursors may also be used in embodiments according to the present invention. The temperature of an injector column that receives such a heated low vapor pressure MO precursor along with other precursors is controlled (e.g., heated) to prevent condensation of the low vapor pressure MO precursor. For example, the injector column may be maintained in a temperature range from about 85 degrees Centigrade to about 200 degrees Centigrade.

In some embodiments, the source vessel that holds the source of the low vapor pressure metalorganic (MO) precursors can be heated to at least 150 degrees Centigrade as well as the lines that deliver the low vapor pressure MO precursor vapor to the CVD reactor chamber. In some embodiments. In some embodiments, the CVD reactor is a horizontal flow reactor that can generate a laminar flow of the low vapor pressure MO precursor vapor over the wafers in the reactor. In some embodiments according to the invention, horizontal flow reactor can include a planetary-type apparatus that rotates during the deposition process and that rotates the wafer stations that hold each of the wafers.

In still further embodiments according to the invention, a heated line that conducts ae low vapor pressure MO precursor vapor to an injector column of a CVD reactor chamber is thermally isolated from the other MO precursors and hydrides. For example, in some embodiments, the heated line that conducts the low vapor pressure MO precursor vapor to the CVD reactor chamber ids provided to the central injector column via a different route than that used to provide the other precursors, such as through a flexible heated line that is connected to a portion of the CVD reactor that moves. In particular, the other precursors may be provided to the central injector column through a lower portion of the CVD reactor that remains stationary when CVD reactor is opened by, for example, lifting the upper portion of the CVD reactor to open the CVD reactor chamber. Accordingly, when the CVD reactor chamber is in the open position, the upper and lower portions of the CVD reactor separate from one another to expose, for example, the planetary arrangements described herein.

As appreciated by the present inventors, providing the low vapor pressure MO precursor vapor to the central injector column by a different path than the other precursors can allow the low vapor pressure MO precursor vapor to be heated to the relatively high temperature without adversely affecting (e.g., heating) the other precursors above room temperature, for example. Accordingly, while the other precursors may be provided via other precursor lines routed though the lower portion that are configured to mate/unmate when the CVD reactor is closed/opened, the heated low vapor pressure MO precursor line to the central injector column can remain a unitary flexible piece that allows the upper portion to move when opened/closed yet still be thermally isolated from the other precursors/precursor lines.

It will be understood that embodiments according to the invention can operate under the control of one or more a control circuits, such as one or more digital processors (e.g., microcontrollers or the like), so that the heating and delivery of the low vapor MO precursor vapor is provided at the temperatures, pressures, amounts and other operational parameters needed to form single crystal piezoelectric layers as described herein. It will be appreciated that control operations described herein may generally be implemented using analog control circuitry, digital control circuitry, or combinations of analog and digital control circuitry.

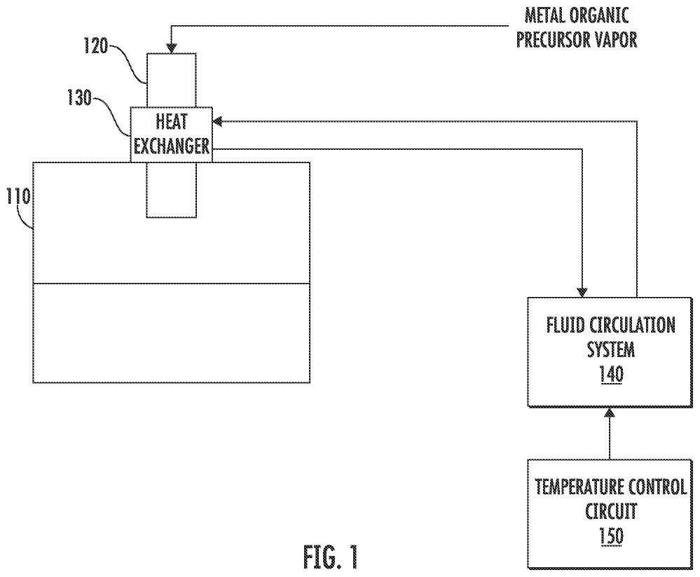

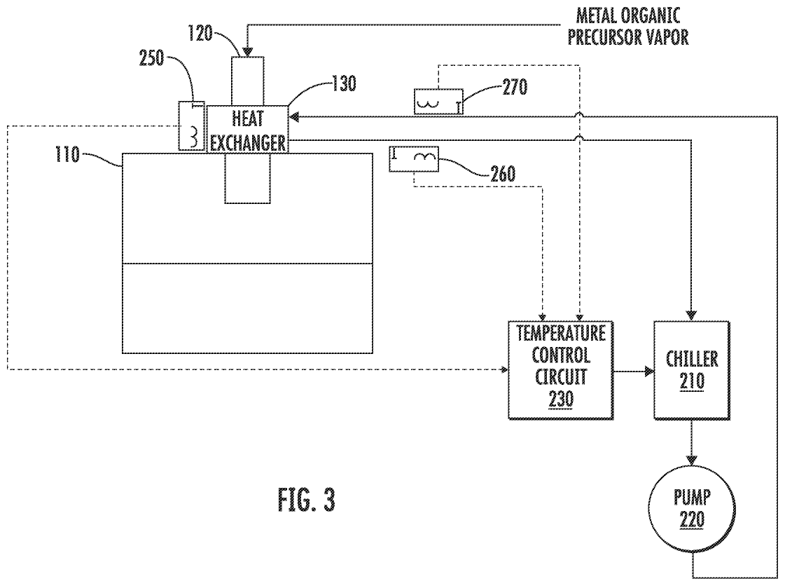

FIG. 1 is a schematic illustration of an apparatus according to some embodiments. A horizontal flow CVD reactor 110 includes an injector column 120 which is configured to receive a low vapor pressure MO precursor vapor. The injector column 120 may comprise, for example, an injector column comprising multiple channels that are configured to receive respective precursor gases and to distribute the received gases using laminar flow across one or more wafers positioned within a reaction chamber of the CVD reactor 110. A temperature of the injector column 120 is controlled by a temperature control system including a heat exchanger 130 in thermal communication with the injector column 120 and a fluid circulator 140 that circulates a heat transfer fluid (e.g., water) through the heat exchanger 130 at a temperature that is controlled by a temperature control circuit 150. It will be appreciated that, although the temperature control system for the injector column 120 shown in FIG. 1 utilizes a heat exchanger 130 with a temperature controlled circulating fluid, other techniques for temperature control may be used, such as temperature control systems that use devices that directly heat the injector column 120, rather than heating a fluid that is passes through a heat exchanger as shown. Some embodiments may also use such direct heating devices in combination with a fluid circulation system, such as one comprising a chiller as shown in FIG. 3 below.

The low vapor pressure MO precursor vapor may be a preheated vapor delivered to the injector column 120 at a temperature in a range from about 160 degrees Centigrade to about 200 degrees Centigrade and a pressure in a range from about 50 mbar to about 1000 mbar. For example, low vapor pressure MO precursor vapor may be delivered to the injector column 120 using any of a number of techniques, such as techniques that utilize a heater precursor vapor line to provide a preheated low pressure MO precursor vapor to a CVD reactor along the lines described in U.S. patent application Ser. No. 16/784,843 (Attorney Docket No. 181246-00022) entitled “APPARATUS FOR FORMING SINGLE CRYSTAL PIEZOELECTRIC LAYERS USING LOW-VAPOR PRESSURE METALORGANIC PRECURSORS IN CVD SYSTEMS AND METHODS OF FORMING SINGLE CRYSTAL PIEZOELECTRIC LAYERS USING THE SAME”, filed Feb. 7, 2020 and incorporated herein by reference in its entirety.

The temperature control circuit 150 may be configured to maintain the injector column 120 at a temperature that prevents or substantially reduces condensation of the low vapor pressure MO precursor vapor in the injector column 120 before it is conveyed into the chamber of the reactor 110 for reaction with other precursors. For example, the temperature control circuit 150 may be configured to maintain low vapor pressure MO precursor vapor within the injector column at a temperature greater than a saturation temperature of the low vapor MO precursor vapor at pressures present within the injector column 120. The temperature control circuit 150 may, for example, maintain the low vapor pressure MO vapor precursor within the injector column 120 at a temperature sufficiently high to prevent saturation and condensation of the low vapor pressure MO precursor vapor while keeping the injector below a desired maximum temperature to prevent overheating during deposition. In some embodiments wherein the injector column 120 is used to introduce the low vapor pressure MO precursor vapor with other precursor gases (as explained in detail below), the temperature control circuit 150 may, for example, cause the fluid circulation system 140 and heat exchanger 130 to maintain the low vapor pressure MO vapor precursor within the injector column 120 at a temperature sufficiently high to prevent saturation and condensation while keeping the injector column 120 below a maximum temperature to prevent or substantially reduce chemical reactions of other precursor gases introduced via the injector column 120.

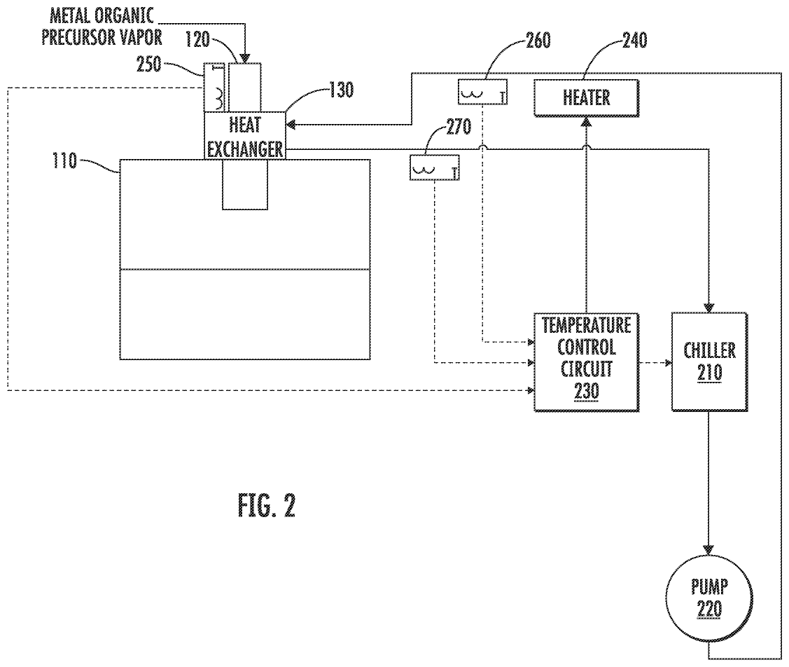

Referring to FIG. 2, according to some embodiments, a temperature control system for an injector column may utilize a circulating cooling system that employs a pump 220, a chiller 210 and a heater 240. A temperature control circuit 230 may control the heater 240 and/or the chiller 220 to maintain the heat exchanger 130 within a desired temperature range. The temperature control circuit 230 may operate responsive to one or more temperature sensors, such as a temperature sensor 250 that senses a temperature of a body of the injector column 120 itself and/or temperatures sensors 260, 270 that sense temperatures of the circulating fluid passing into or out of the heat exchanger 130. Referring to FIG. 3, in some embodiments, the injector column 120 may be heated by ambient conditions (e.g., by heat from the chamber of the reactor 110), and the temperature of the injector column may be controlled using just the chiller 210, obviating the need for the additional heater 240 shown in FIG. 2.

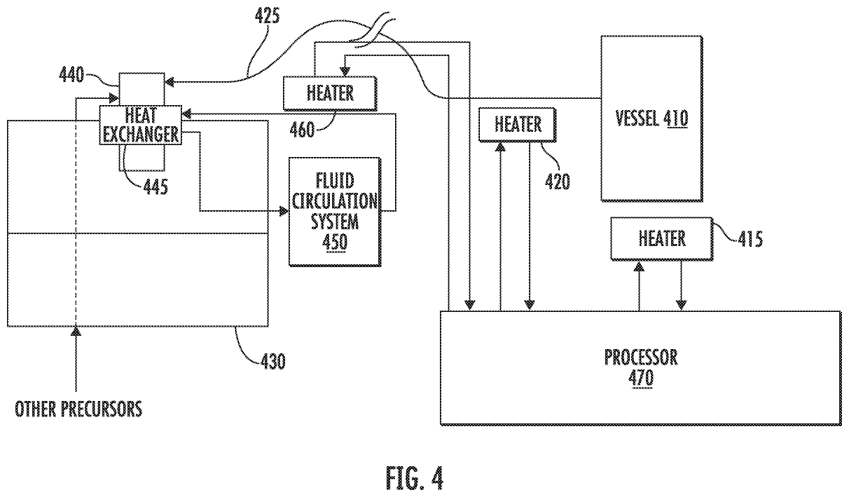

FIG. 4 is a schematic representation of a CVD system according to further embodiments of the invention. The CVD system includes a horizontal flow CVD reactor 430 supplied with a heated low vapor pressure MO precursor vapor routed to the CVD reactor 430 via a heated line 425 that is thermally isolated from other precursors delivered to the CVD reactor 430. A central injector column 440 penetrates an upper part of the reactor 430 and is coupled to the heated low vapor pressure MO precursor line 425 that carries a low vapor pressure MO precursor vapor. The central injector column 440 may be also coupled to other lines that carry respective other precursors to the CVD reactor 430. The heated low vapor pressure MO precursor line 425 is heated by a heater 420 that operates under the control of a processor circuit 470 to maintain the temperature of the line 425 so that the precursor vapor therein is provided to the injector column 440 at a temperature in a range between about 160 degrees Centigrade to about 200 degrees Centigrade.

As further shown in FIG. 4, other precursors can also be provided to the central injector column 440 via one or more paths that are separated from the heated line 425. In some embodiments, the other precursors can include other metal organic precursors as wells as hydrides. It will be understood that the path for delivering the other precursors may be thermally isolated from the heated line 425 so that the heated precursor vapor can be delivered to the central injector column 440 without substantially affecting the temperature of the other precursors before entry into the injector column 440. In some embodiments, the heated precursor line 425 may be spaced apart from lines that carry the other precursors to avoid inadvertently heating the other precursors with the heated line 425.

As further shown in FIG. 1, a heater 420 is thermally coupled to the heated line 425 and is controlled by the processor circuit 470 to maintain the temperature of the heated low vapor pressure metal organic precursor vapor delivered to the injector column 440 within the desired temperature range via a feedback control loop. Another heater 425 may be provided to heat a low vapor pressure precursor source vessel 410, which can hold the material which generates the low vapor pressure MO precursor vapor. The processor circuit 470 can use feedback control circuit to control the operations of the heaters 415, 420. It will be understood that the heater 420 may include different segments that are each thermally coupled to the heated line 425, which can all be controlled by the processor circuit 470 as an integrated unit. It will be understood that the processor circuit 470 can adjust the temperature of the low vapor pressure MO precursor vapor to be greater than a target value to allow for heat loss during the transfer to the injector column so that the vapor is delivered to the injector column 440 in a desired temperature range.

As further illustrated in FIG. 4, in some embodiments, an additional temperature control system may be provided for the injector column 440 such that a temperature of the column 440 to be maintained within a desired range that inhibits or prevents condensation of the preheated low vapor pressure MO precursor vapor within the column 440. As shown, the temperature control system may include a heat exchanger 445 in thermal communication with the injector column 440. The temperature control system further includes a fluid circulation system fluidically coupled to the heat exchanger 445 and includes a fluid circulator 450 (e.g., a pump and reservoir) and a heater 460 that heats fluid circulated through the heat exchanger 445 by the fluid circulator 450. The heater 460 may be controlled by a feedback control loop including the processor circuit 470 to maintain a desired temperature for the injector column 440. It will be appreciated that, although the temperature control system for the injector column 440 shown in FIG. 4 utilizes a heat exchanger 445 with a temperature controlled circulating fluid, other techniques for temperature control may be used, such as temperature control systems that use devices that directly heat the injector column 440, rather than heating a fluid that is passes through a heat exchanger as shown. Some embodiments may also use such direct heating devices in combination with a fluid circulation system, such as one comprising a chiller as shown in FIG. 3.

The temperature control system for the injector column 440 may maintain the injector column at a temperature in a range from about 85 degrees Centigrade to about 200 degrees Centigrade. In further embodiments, the temperature control system may maintain the injector column at a temperature in a range from about 150 degrees Centigrade to about 200 degrees Centigrade. In some embodiments, the temperature at which the temperature control system maintains the injector column at a temperature that maintains the low vapor pressure MO precursor vapor within the injector column 440 above a saturation temperature of the low vapor pressure MO precursor vapor at pressures present within the injector column 440 such that a significant amount of the vapor does not condense within the injector column 440. For example, the pressure within the injector column 440 may be in a range from about 50 mbar to about 1000 mbar, and the temperature control system for the injector column 440 may be configured to maintain the low vapor pressure MO precursor vapor within the injector column 440 above a maximum saturation temperature for that pressure range, for example, in a range from about 85 degrees Centigrade to about 200 degrees Centigrade.

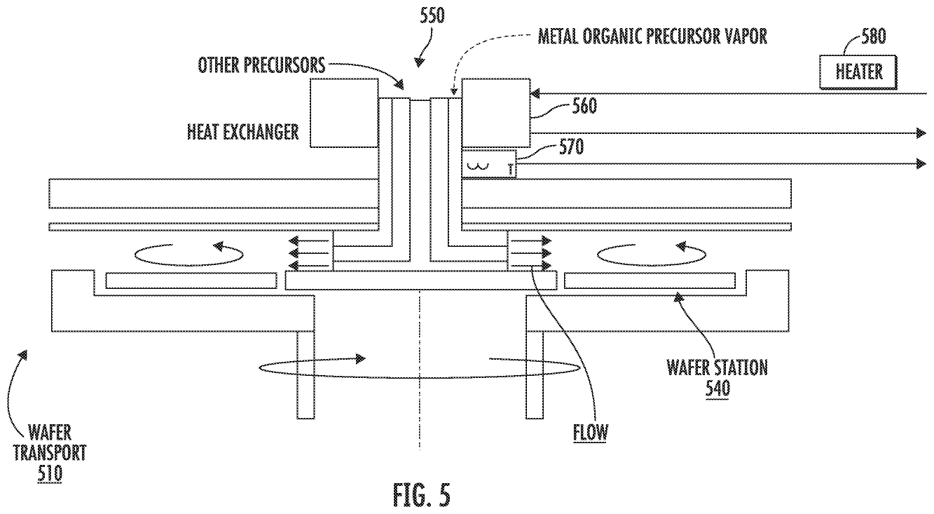

FIG. 5 is a schematic representation of components of a reactor along the lines described above with reference to FIG. 4. A planetary wafer transport 510 within a lower portion of a reactor chamber rotates during laminar flow of the low vapor pressure MO precursor vapor over wafers positioned at wafer stations 540 that rotate on the planetary wafer transport 510. The planetary wafer transport 510 rotates in a first direction. The planetary wafer transport 510 includes a plurality of wafer stations 540, each of which can hold a single wafer on which single crystal piezoelectric layers can be formed in some embodiments according to the invention. Each of the wafer stations 540 rotates in a second direction opposite to the first direction.

A temperature-controlled central injector column 550 provides a horizontal laminar flow of precursor across the surface of the wafers as the planetary wafer transport 510 and the wafer stations 520 rotate. Low vapor pressure MO precursor vapor is introduced to the central injector column 550 in a channel that is spaced apart from channels through with other precursors are introduced to the central injector column 550 to prevent premature reaction among the precursors. A heat exchanger 560 is thermally coupled to the injector column 550 and receives a circulating fluid (e.g., water) that is heated by a heater 580, which may be controlled as described above. A temperature of the heat exchanger 560 may be sensed by a temperature sensor (e.g., a thermocouple or thermistor), and fed back to a control system (e.g., a processor circuit) that controls the heater 580.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the various embodiments described herein. As used herein, the term “and/or” includes any and all combinations of one or more of the associated listed items.

The terminology used herein is for the purpose of describing particular embodiments only and is not intended to be limiting to other embodiments. As used herein, the singular forms “a”, “an” and “the” are intended to include the plural forms as well, unless the context clearly indicates otherwise. It will be further understood that the terms “comprises,” “comprising,” “includes” and/or “including”, “have” and/or “having” when used herein, specify the presence of stated features, integers, steps, operations, elements, and/or components, but do not preclude the presence or addition of one or more other features, integers, steps, operations, elements, components, and/or groups thereof. Elements described as being “to” perform functions, acts and/or operations may be configured to or other structured to do so.

Unless otherwise defined, all terms (including technical and scientific terms) used herein have the same meaning as commonly understood by one of ordinary skill in the art to which various embodiments described herein belong. It will be further understood that terms used herein should be interpreted as having a meaning that is consistent with their meaning in the context of this specification and the relevant art and will not be interpreted in an idealized or overly formal sense unless expressly so defined herein.

As will be appreciated by one of skill in the art, various embodiments described herein may be embodied as a method, data processing system, and/or computer program product. Furthermore, embodiments may take the form of a computer program product on a tangible computer readable storage medium having computer program code embodied in the medium that can be executed by a computer.

Any combination of one or more computer readable media may be utilized. The computer readable media may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a computer readable storage medium may be any tangible medium that can contain or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable signal medium may be transmitted using any appropriate medium, including but not limited to wireless, wired, optical fiber cable, RF, etc., or any suitable combination of the foregoing.

Computer program code for carrying out operations for aspects of the present disclosure may be written in any combination of one or more programming languages, including an object oriented programming language such as Java, Scala, Smalltalk, Eiffel, JADE, Emerald, C++, C#, VB.NET, Python or the like, conventional procedural programming languages, such as the “C” programming language, Visual Basic, Fortran 2003, Perl, COBOL 2002, PHP, ABAP, dynamic programming languages such as Python, Ruby and Groovy, or other programming languages, such as a programming language for a FPGA, Verilog, System Verilog, Hardware Description language (HDL), and VHDL,. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider) or in a cloud computer environment or offered as a service such as a Software as a Service (SaaS).

Some embodiments are described herein with reference to flowchart illustrations and/or block diagrams of methods, systems and computer program products according to embodiments. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create a mechanism for implementing the functions/acts specified in the flowchart and/or block diagram block or blocks.

These computer program instructions may also be stored in a computer readable medium that when executed can direct a computer, other programmable data processing apparatus, or other devices to function in a particular manner, such that the instructions when stored in the computer readable medium produce an article of manufacture including instructions which when executed, cause a computer to implement the function/act specified in the flowchart and/or block diagram block or blocks. The computer program instructions may also be loaded onto a computer, other programmable instruction execution apparatus, or other devices to cause a series of operational steps to be performed on the computer, other programmable apparatuses or other devices to produce a computer implemented process such that the instructions which execute on the computer or other programmable apparatus provide processes for implementing the functions/acts specified in the flowchart and/or block diagram block or blocks.

It is to be understood that the functions/acts noted in the blocks may occur out of the order noted in the operational illustrations. For example, two blocks shown in succession may in fact be executed substantially concurrently or the blocks may sometimes be executed in the reverse order, depending upon the functionality/acts involved. Although some of the diagrams include arrows on communication paths to show a primary direction of communication, it is to be understood that communication may occur in the opposite direction to the depicted arrows.

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall support claims to any such combination or subcombination.

What is claimed is:

1. An apparatus for forming semiconductor films, the apparatus comprising:
a chemical vapor deposition (CVD) reactor;
an injector column that provides a metal organic precursor vapor into a reactor chamber of the CVD reactor;
a heater in thermal communication with the injector column; and
a control circuit configured to control the heater and thereby maintain the metal organic precursor vapor in the injector column above a saturation temperature.

2. The apparatus of claim 1, wherein the control circuit is configured to control the heater to maintain a temperature of the metal organic precursor vapor in the injector column in a temperature range from about 85 degrees Centigrade to about 200 degrees Centigrade.

3. The apparatus of claim 1, further comprising:
a fluid channel in thermal communication with the injector column; and
a fluid circulation system configured to pass a fluid through the fluid channel,
wherein the heater is in thermal communication with the fluid.

4. The apparatus of claim 1, wherein a temperature of the metal organic precursor vapor entering the injector column is in a range from about 160 degrees Centigrade to about 200 degrees Centigrade and a pressure of the metal organic precursor vapor entering the injector column is in a range from about 50 mbar to about 1000 mbar.

5. The apparatus of claim 1, further comprising a heated precursor line coupled to the injector column.

6. The apparatus of claim 5, wherein the heated precursor line is configured to maintain a temperature of a metal organic precursor vapor delivered to the injector column in a range from about 160 degrees Centigrade to about 200 degrees Centigrade.

7. An apparatus for forming semiconductor films, the apparatus comprising:
a CVD reactor;
an injector column that provides a metal organic precursor vapor into a reactor chamber of the CVD reactor;
a heat exchanger in thermal communication with the injector column; and
a fluid circulation system in fluid communication with the heat exchanger and configured to maintain a temperature of the metal organic precursor vapor in the injector column in a range from about 85 degrees Centigrade to about 200 degrees Centigrade.

8. The apparatus of claim 7, wherein the fluid circulation system is configured to circulate a fluid through the heat exchanger and comprises a control circuit is configured to control a temperature of the fluid.

9. The apparatus of claim 8, wherein the fluid circulation system comprises a chiller and/or a heater and wherein the control circuit is configured to control the chiller and/or the heater.

10. The apparatus of claim 7, wherein a temperature of the metal organic precursor vapor entering the injector column is in a range from about 160 degrees Centigrade to about 200 degrees Centigrade and a pressure of the metal organic precursor vapor entering the injector column is in a range from about 50 mbar to about 1000 mbar.

11. The apparatus of claim 7, further comprising a heated precursor line coupled to the injector column.

12. The apparatus of claim 11, wherein the heated precursor line is configured to maintain a temperature of a metal organic precursor vapor delivered to the injector column at a temperature in a range from about 160 degrees Centigrade to about 200 degrees Centigrade.

13. A method of forming semiconductor films, the method comprising:
providing a metal organic precursor vapor to an injector column of a CVD reactor; and
controlling a heater in thermal communication with the injector column such that the metal organic precursor vapor in the injector column is maintained above a saturation temperature of the metal organic precursor vapor.

14. The method of claim 13, wherein controlling heater comprises controlling the heater to maintain a temperature of the metal organic precursor vapor in the injector column in a temperature range from about 85 degrees Centigrade to about 200 degrees Centigrade.

15. The method of claim 13, further comprising:
providing a fluid channel in thermal communication with the injector column and
a fluid circulation system configured to pass a fluid through the fluid channel,
wherein the heater is in thermal communication with the fluid.

16. The method of claim 13, wherein a temperature of the metal organic precursor vapor entering the injector column is in a range from about 160 degrees Centigrade to about 200 degrees Centigrade and a pressure of the metal organic precursor vapor entering the injector column is in a range from about 50 mbar to about 1000 mbar.

17. The method of claim 13, further comprising heating a precursor line that provides the metal organic precursor vapor to the injector column.

18. The method of claim 17, wherein the heated precursor line is configured to maintain a temperature of a metal organic precursor vapor delivered to the injector column in a range from about 160 degrees Centigrade to about 200 degrees Centigrade.
